(19) United States
(12) Patent Application Publication
(10) Pub. No.: US 2024/0381746 A1
(43) Pub. Date: Nov. 14, 2024

(54) DISPLAY DEVICE

(71) Applicant: TAIZHOU GUANYU TECHNOLOGY CO., LTD., ZHEJIANG PROVINCE (CN)

(72) Inventors: FU-YUAN TUAN, NEW TAIPEI CITY (TW); SZUTSUNG WU, TAOYUAN CITY (TW); HSIENHUNG CHENG, ZHEJIANG PROVINCE (CN)

(21) Appl. No.: 18/690,710

(22) PCT Filed: Sep. 6, 2022
(86) PCT No.: PCT/CN2022/117317

§ 371 Date: Mar. 8, 2024

Related U.S. Application Data
(60) Provisional application No. 63/242,096, filed on Sep. 9, 2021.

(30) Foreign Application Priority Data
Aug. 3, 2022 (CN) 202210925085.9

(51) Int. Cl. H10K 59/80; H10K 59/60

(52) U.S. Cl. CPC H10K 59/879; H10K 59/60

(57) ABSTRACT

The present disclosure provides a display device and a method for manufacturing a display device. The display device includes a substrate, a light emitting unit, an optical element layer and a photosensitive layer. The light emitting unit is disposed on the substrate. The optical element layer is disposed on the light emitting unit. The optical element layer has a first curved surface. The first curved surface has a central portion and a peripheral portion. The central portion is closer to the substrate than the peripheral portion. The photosensitive layer is in contact with the optical element layer.

### CROSS-REFERENCE TO RELATED APPLICATIONS

This application claims priority of Chinese patent application entitled “DISPLAY DEVICE” filed on Aug. 3, 2022 (application No. 202210925085.9), and claims priority of U.S. Provisional Application No. 63/242,096, filed on Sep. 9, 2021; the entire contents of which are incorporated by reference in this application.

### BACKGROUND OF THE PRESENT DISCLOSURE

### Technical Field

The present disclosure relates to a display device, and more particularly to a display device including an optical element layer.

### Background

Display devices including an optical element layer are extensively applied in most electronic apparatuses, and there has been an increasing demand for large-scale display devices in the recent years. However, a method for manufacturing a display device contains steps with poor yield rates. In fact, one commonly known challenge is how to improve the manufacturing yield rate while forming a display device having an optical element layer. Thus, the industry of display devices seeks a method for solving the issues above.

### SUMMARY

A display device includes a substrate, a light emitting unit, an optical element layer and a photosensitive layer. The light emitting unit is disposed on the substrate. The optical element layer is disposed on the light emitting unit. The optical element layer has a first curved surface. The first curved surface has a central portion and a peripheral portion. The central portion is closer to the substrate than the peripheral portion. The photosensitive layer is in contact with the optical element layer.

In some embodiments, the optical element layer includes a lens.

In some embodiments, the display device excludes a filter layer.

In some embodiments, the light emitting unit is an organic light emitting diode (OLED).

In some embodiments, the display device further includes a cover plate. The cover plate is disposed on the optical element layer. The optical element layer is in direct contact with the cover plate.

In some embodiments, the display device further includes the photosensitive layer. The photosensitive layer is in contact with the optical element layer, and has a second curved surface. The second curved surface of the photosensitive layer is in contact with the first curved surface of the optical element layer.

A method for manufacturing a display device includes: providing a substrate; forming a light emitting unit on the substrate; providing an optical element layer on the light emitting unit, wherein the optical element layer has a first curved surface, the first curved surface has a central portion and a peripheral portion, and the central portion is closer to the substrate than the peripheral portion; and providing a cover plate to cover the optical element layer.

In some embodiments, the method further includes: forming a photosensitive layer having a second curve surface, wherein the optical element layer is formed on the second curved surface of the photosensitive layer.

In some embodiments, the forming of the optical element layer includes: forming the photosensitive layer on the light emitting unit; performing an exposure operation to form the second curved surface of the photosensitive layer; and forming the optical element layer on the second curved surface of the photosensitive layer.

In some embodiments, the forming of the optical element layer includes: forming the photosensitive layer on a cover plate; performing an exposure operation to form the second curved surface of the photosensitive layer; forming the optical element layer on the second curved surface of the photosensitive layer; and adhering the optical element layer onto the light emitting unit.

### BRIEF DESCRIPTION OF THE DRAWINGS

FIG. 1 is a cross-sectional view of a display device according to some embodiments;

FIG. 2 is a cross-sectional view of a display device according to some embodiments;

FIG. 3A to FIG. 3E are brief diagrams of a display device in different manufacturing stages of a method according to some embodiments of the present disclosure;

FIG. 4A to FIG. 4E are brief diagrams of a display device in different manufacturing stages of a method according to some embodiments of the present disclosure; and

FIG. 5A to FIG. 5D are brief diagrams of a display device in different manufacturing stages of a method of a comparison example.

### DETAILED DESCRIPTION OF THE EMBODIMENTS

Numerous different embodiments or examples are provided in the present disclosure below to implement different characteristics of the present application. Specific examples of elements and configurations are as described below in the aim of simplifying the disclosure of the present application. However, these examples are merely examples and are not to be construed as limitations to the present application. For example, a first feature formed on, over or above a second feature can include an embodiment in which the first and second features are in direct contact, and can also include an embodiment in which another feature is formed between the first and second features and the first and second features are thus not in direct contact. Moreover, numerals, symbols and/or letters may be repeated in different examples. Such repetition is for the purpose of simplicity and clarity, and does not dictate relations between the various embodiments and/or structures discussed.

In addition, spatial correspondence terms used in the present application such as “under”, “lower than”, “below”, “more that”, “higher than” and the like can be used for simple description so as to explain a relation of one element or feature in a drawing with respect to another element or feature. In addition to orientations illustrated in the drawings, these spatial correspondence terms further include different orientations of an apparatus in use or in operation. An apparatus can be oriented (rotated by 90 degrees or other orientations), and the spatial correspondence description used in the present application can be interpreted accordingly.

Despite that numeric ranges and parameters disclosed in the broadest range of the present disclosure are approximate values, the values stated in specific embodiments are to be as accurate as possible. However, any numeral intrinsically includes a certain error caused by a standard deviation obtained from individual testing and measurement. Moreover, in the literature below, the term “about/approximate” usually refers to less than 10%, 5%, 1% or 0.5% of a predetermined value or range. Alternatively, the term “about/approximate” refers to within an acceptable standard error of a mean value considered by a person of ordinary skill in the art. Apart from operation/working examples, unless otherwise specified, it is to be understood that the amount, period of time, temperature, operating conditions, ratio of quantity of materials, as well as all numerical ranges, quantities, values and ratios of the like, are to be modified by the term “about/approximate” in all circumstances. Thus, unless described otherwise, the numerical values and parameters of the claims set forth in the present disclosure can be regarded as approximate value that are variable according to requirements. Each numerical value or parameter is to be interpreted at least in light of a quantity of effective numbers reported and by applying common rounding techniques. In the present disclosure, a range can represent from one endpoint to the other endpoint, or between these two endpoints. Unless otherwise specified, all ranges disclosed in the present literature include endpoints.

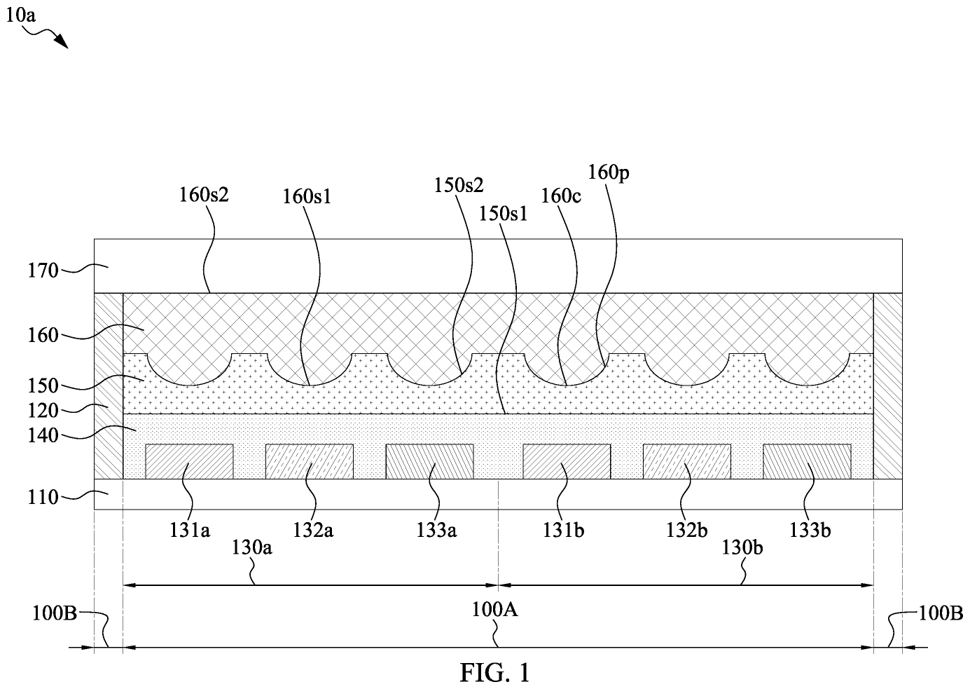

FIG. 1 shows a cross-sectional view of a display device 10a according to some embodiments.

The display device 10a includes a light emitting region 100A and a peripheral region 100B. The light emitting region 100A can be defined as a region configured to emit light in the display device 10a, and the peripheral region 100B can be defined as a non-light emitting region in the display device 10a.

In some embodiments, the display device 10a includes a substrate 110, a support structure 120, a pixel 130a, a pixel 130b, a filler layer 140, a photosensitive layer 150, an optical element layer 160 and a cover plate 170.

In some embodiments, the substrate 110 includes a base material (not shown), a dielectric layer (not shown), and one or more circuits (not shown) disposed on the base material or in the base material. In some embodiments, the base material is a transparent base material, or is at least partially transparent. In some embodiments, the base material is a non-flexible base material, and a material of such base material can include glass, quartz, low-temperature polysilicon (LTPS) or other appropriate materials. In some embodiments, the base material is a flexible substrate, and a material of such base material can include transparent epoxy resin, polyimide, polyvinyl chloride, methyl methacrylate or other appropriate materials. The dielectric layer is disposed on the base material as needed. In some embodiments, the dielectric layer can include silicon oxide, silicon nitride, silicon oxynitride, or other appropriate materials.

In some embodiments, the circuit can include a complementary metal oxide semiconductor (CMOS) circuit, or multiple transistors and multiple capacitors adjacent to the transistors, wherein the transistors and the capacitors are formed on the dielectric layer. In some embodiments, each of the transistors is a thin-film transistor (TFT). Each of the transistors includes a source/drain region (including at least one source region and one drain region), a channel region located in the source-drain region, a gate electrode disposed above the channel region, and a gate insulator located between the channel region and the gate electrode. The channel region of the transistor can be formed of a semiconductor material, for example, silicon or other elements selected from group IV or group III and group V.

The gate electrode can be formed of a conductive material, for example, a metal, silicide or a metal alloy. In some embodiments, the gate electrode can be a composite structure which includes multiple different layers, and these layers can be distinguished from one another by applying an etchant and observing under a microscope. In some embodiments, the substrate 110 includes components such as an interlayer dielectric structure and a first metal layer. The interlayer dielectric structure is disposed on the circuit or the transistor. The first metal layer or other wiring layers can be used to electrically connect to a light emitting unit in the pixel 130a and/or the pixel 130b.

The support structure 120 is disposed in the peripheral region 100B of the display device 10a. In some embodiments, the support structure 120 is formed of black resin. The support structure 120 can be used to support the cover plate 170 and protect components in the support structure 120.

The pixel 130a and the pixel 130b are disposed in the light emitting region 100A of the display device 10a. In some embodiments, the pixel 130a includes light emitting units 131a, 132a and 133a. In some embodiments, the pixel 130b includes light emitting units 131b, 132b and 133b. Although one pixel 130a or pixel 130b depicted in FIG. 1 can include three light emitting units, the present disclosure is not limited to such example. In some embodiments, the pixel 130a and the pixel 130b do not include a light shielding structure, for example, black photoresist, therebetween.

In some embodiments, each of the light emitting units 131a, 132a, 133a, 131b, 132b and 133b can be an organic light emitting diode (OLED), a micro light emitting diode (LED) or mini LED, a quantum dot LED (QLED) or other appropriate light emitting units.

In some embodiments, the light emitting unit 131a, 132a, 133a, 131b, 132b and 133b are OLEDs. In some embodiments, each of the light emitting unit 131a, 132a, 133a, 131b, 132b and 133b can include a cathode, an electron transport layer, a light emitting layer, a hole transport layer, an anode, other appropriate components.

In some embodiments, the light emitting units 131a, 132a, and 133a (or the light emitting units 131b, 132b and 133b) can emit light of different wavelengths. In some embodiments, the light emitting unit 131a and the light emitting unit 131b can emit red light (for example, light of a wavelength between 620 nm and 780 nm), the light emitting unit 132a and the light emitting unit 132b can emit green light (for example, light of a wavelength between 500 nm and 580 nm), and the light emitting unit 133a and the light emitting unit 133b can emit blue light (for example, light of a wavelength between 400 nm and 500 nm). In some embodiments, since one pixel 130a or pixel 130b includes three light emitting units capable of emitting different wavelengths, colors presented by the one pixel can be determined by intensities of the lights emitted by these three light emitting units. Thus, the display device 10a does not need a filter layer (or a color filer layer). In some embodiments, the display device 10a does not include a red filter layer (for example, a filter layer allowing light of a wavelength between 620 nm and 780 nm to pass through). In some embodiments, the display device 10a does not include a green filter layer (for example, a filter layer allowing light of a wavelength between 500 nm and 580 nm to pass through). In some embodiments, the display device 10a does not include a blue filter layer (for example, a filter layer allowing light of a wavelength between 400 nm and 500 nm to pass through). In a comparison example, light emitting units of a display device are formed by OLEDs that emit white light. In this comparison example, the display device needs filter layers corresponding to the individual colors to emit light in different colors. Compared to the comparison example, the display device 10a does not include any filter layer, and thus a thickness of the display device 10a can be reduced.

The filler layer 140 is disposed on the substrate 110. The filler layer 140 can include a substantially transparent material, for example, resin or other appropriate materials, and can include any desired filler. Light transmittance of the filler layer 140 can be greater than 85%, and is, for example, 85%, 88%, 90%, 93%, 95%, 97%, 98% or 99%.

The photosensitive layer 150 is disposed on the light emitting units 131a, 132a, 133a, 131b, 132b and 133b. In the present disclosure, the term “photosensitive layer” refers to a photosensitive layer having compositions (or ingredients) that can be patterned by steps such as irradiation, exposure and/or development, and can be cured by an operation such as irradiation or heating. The photosensitive layer 150 is disposed on the filler layer 140. In some embodiments, the photosensitive layer 150 is located between the substrate 110 and the optical element layer 160. In some embodiments, the photosensitive layer 150 includes a photosensitive organic material. The photosensitive organic material can include a polycyclic aromatic compound, an alkene, or other appropriate materials.

The photosensitive layer 150 can include a surface 150s1 (or a lower surface) and a surface 150s2 (or an upper surface) opposite to the surface 150s1. The surface 150s1 is closer to the substrate 110 than the surface 150s2. In some embodiments, the surface 150s1 of the photosensitive layer 150 is in direct contact with or face the filler layer 140. In some embodiments, the surface 150s1 of the photosensitive layer 150 is a substantially flat surface. In some embodiments, the surface 150s2 of the photosensitive layer 150 includes a curved surface. In some embodiments, the surface 150s2 of the photosensitive layer 150 includes a plurality of recessed contours (or recessed profiles) (for example, recessed toward the substrate 110). Each of the recessed contours can correspond to one light emitting unit.

In some embodiments, the optical element layer 160 is disposed on the photosensitive layer 150. In some embodiments, the optical element layer 160 is configured to change a light path of light emitting from a light emitting unit. In some embodiments, the optical element layer 160 includes a lens or other appropriate components. The optical element layer 160 includes a surface 160s1 (or a lower surface) and a surface 160s2 (or an upper surface) opposite o the surface 160s1. In some embodiments, the surface 160s1 of the optical element layer 160 is in direct contact with the surface 150s2 of the photosensitive layer 150. In some embodiments, the surface 160s1 of the optical element layer 160 includes a curved surface. In some embodiments, the surface 160s1 of the optical element layer 160 includes a plurality of protruding contours (or protruding profiles). Each of the protruding contours can correspond to one light emitting unit. In some embodiments, each of the protruding contours of the surface 160s1 of the optical element layer 160 can correspond to the recessed contour of the surface 150s2 of the photosensitive layer 150. In some embodiments, the surface 160s1 of the optical element layer 160 has a central portion 160c and a peripheral portion 160p, wherein the central portion 160c is closer to the substrate 110 than the peripheral portion 160p. Herein, the central portion 160c can refer to a central portion of a contour, and the peripheral portion 160p can refer to a region which surrounds the central portion 160c and located at an outer periphery in comparison with the central portion 160c. In some embodiments, the surface 160s2 of the optical element layer 160 is a substantially flat surface.

In other embodiments, the surface 150s2 of the photosensitive layer 150 can include a plurality of protruding contours, and the surface 160s1 of the optical element layer 160 can include a plurality of recessed contours.

The cover plate 170 is disposed on the optical element layer 160. In some embodiments, the cover plate 170 is in direct contact with the surface 160s2 of the optical element layer 160. The cover plate 170 covers the support structure 120 and the optical element layer 160. In some embodiments, the cover plate 170 includes a substantially transparent component, for example, glass or other appropriate components.

In this embodiment, a curved surface (for example, the surface 160s1) of the optical element layer 160 is directly formed on the photosensitive layer 150 having a curved contour. In a comparison example, the curved surface of the optical element layer is formed by a reflow operation. A temperature of the reflow operation is at least greater than 130° C. At this temperature, components such as the light emitting units can be damaged. In comparison, in this embodiment, the reflow operation is not required, so the photosensitive layer 150 and the optical element layer 160 can be directly formed on a structure including the substrate 110 and the components above the substrate 110. Thus, the photosensitive layer 150 and the optical element layer 160 do not need to be disposed on another carrier, and it is not necessary to perform an alignment operation before the carrier is adhered to the substrate 110. In this embodiment, yield rate loss caused by the alignment operation can be reduced. Compared to the comparison example, the display device 10a can be formed by a method with a higher yield rate.

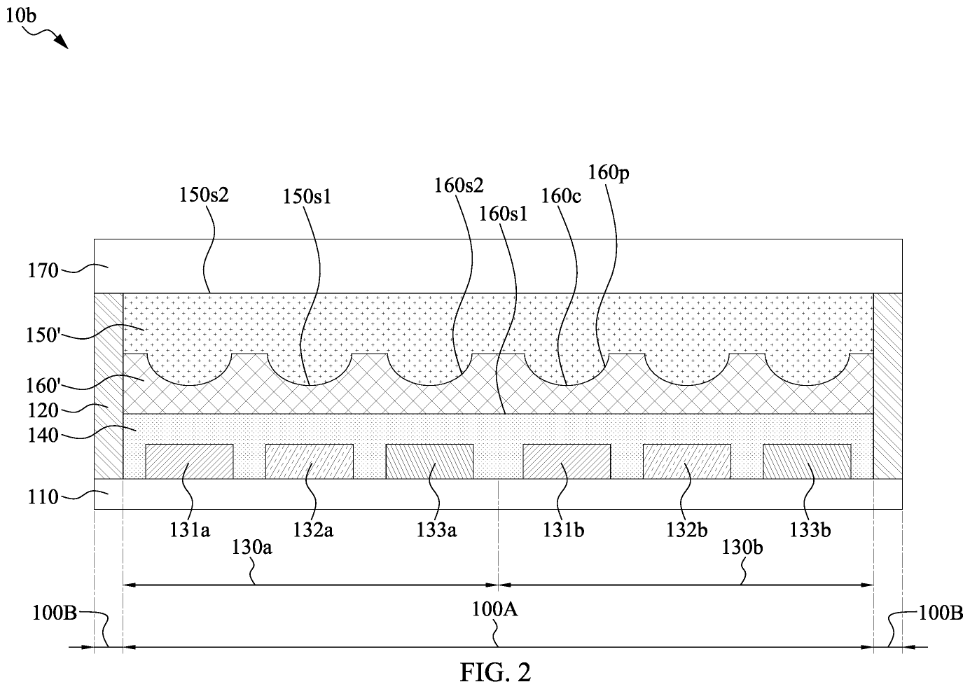

FIG. 2 shows a cross-sectional view of a display device 10b according to some embodiments. The display device 10b has a structure similar to that of the display device 10a, and differs in that the display device 10b includes a photosensitive layer 150′ and an optical element layer 160′.

In some embodiments, the optical element layer 160′ is located between the substrate 110 and the photosensitive layer 150′. The optical element layer 160′ includes a surface 160s1 and a surface 160s2. In some embodiments, the surface 160s1 of the optical element layer 160′ is a substantially flat surface. In some embodiments, the surface 160s1 of the optical element layer 160′ is in direct contact with or face the filler layer 140. In some embodiments, the surface 160s2 of the optical element layer 160′ includes a curved surface. In some embodiments, the surface 160s2 of the optical element layer 160′ includes a plurality of recessed contours. Each of the recessed contours can correspond to one light emitting unit. In some embodiments, the surface 160s2 of the optical element layer 160′ has a central portion 160c and a peripheral portion 160p, wherein the central portion 160c is closer to the substrate 110 than the peripheral portion 160p.

In some embodiments, the photosensitive layer 150′ is disposed on the optical element layer 160′. The photosensitive layer 150′ includes a surface 150s1 and a surface 150s2. In some embodiments, the surface 150s1 of the photosensitive layer 150′ is in direct contact with the surface 160s2 of the optical element layer 160′. In some embodiments, the surface 150s1 of the photosensitive layer 150′ includes a plurality of protruding contours. Each of the protruding contours can correspond to one light emitting unit. In some embodiments, each of the protruding contours of the surface 150s1 of the photosensitive layer 150′ can correspond to the recessed contour of the surface 160s2 of the optical element layer 160′. In some embodiments, the surface 150s2 of the photosensitive layer 150′ is a substantially flat surface.

In some embodiments, the cover plate 170 is in direct contact with the surface 150s2 of the photosensitive layer 150′.

In other embodiments, the surface 160s2 of the optical element layer 160′ can include a plurality of protruding contours, and the surface 150s1 of the photosensitive layer 150′ can include a plurality of recessed contours.

In this embodiment, the surface 160s2 of the optical element layer 160′ is directly formed on the surface 150s1 of the photosensitive layer 150′ having a curved contour. In the comparison example, the curved surface of the optical element layer is formed by a reflow operation. A temperature of the reflow operation is at least greater than 130° C. At this temperature, components such as the light emitting units can be damaged. Compared to the comparison example, in this embodiment, the display device 10b can be formed without performing the reflow operation.

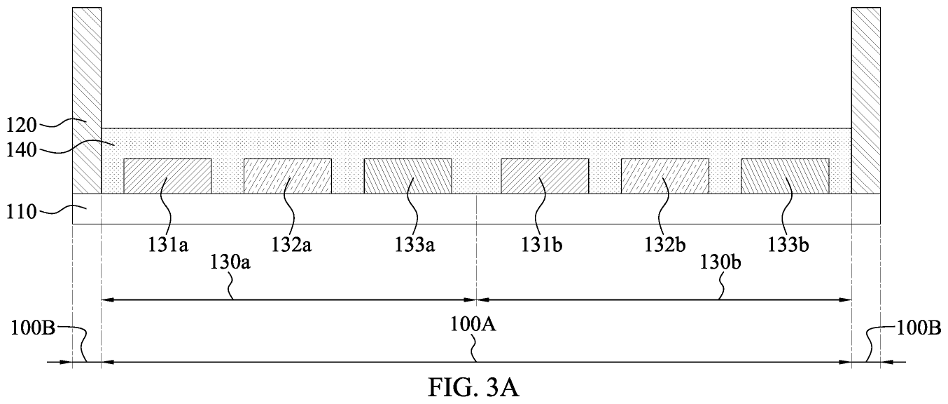

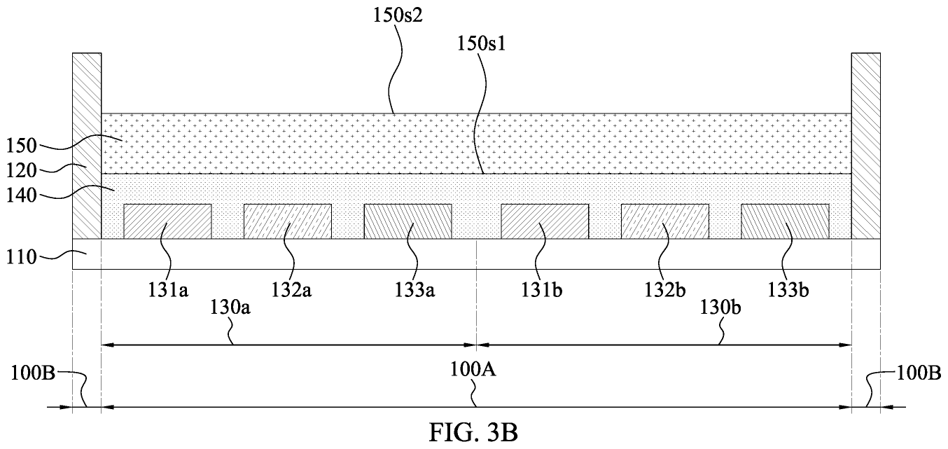

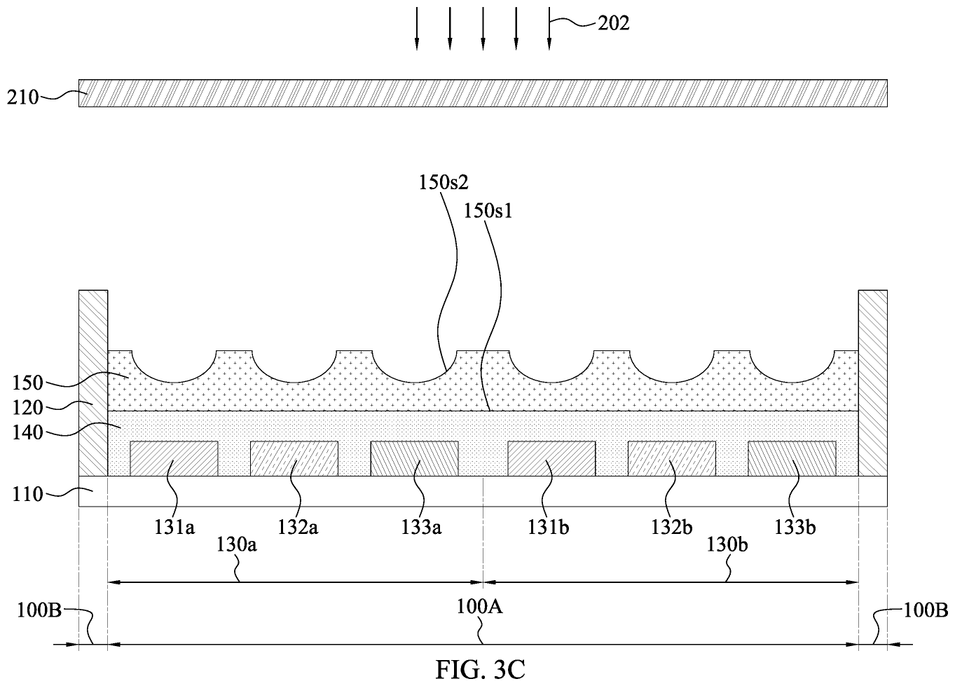

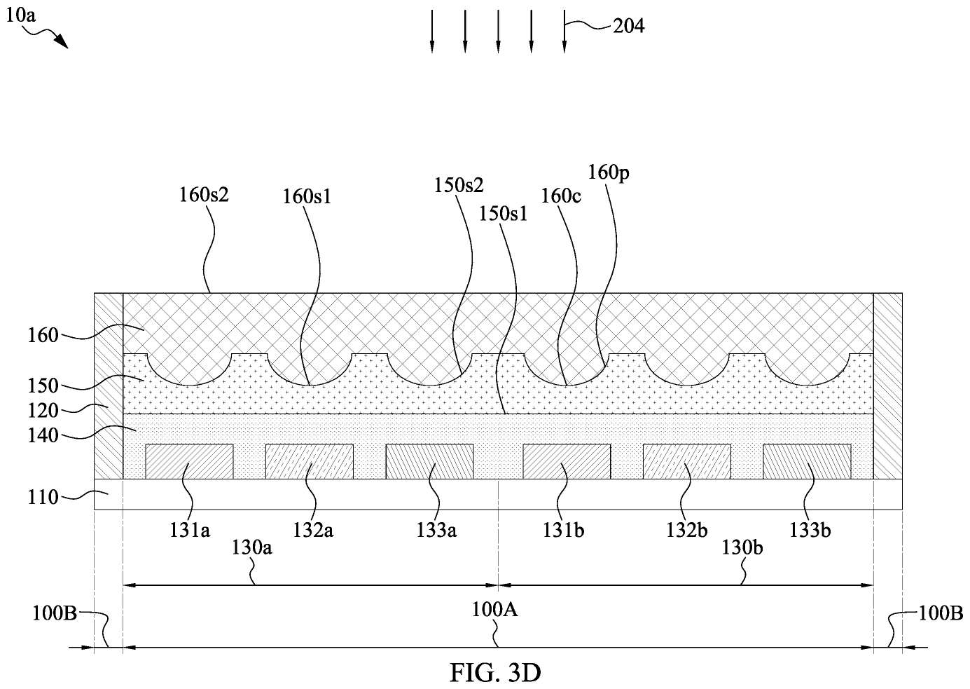

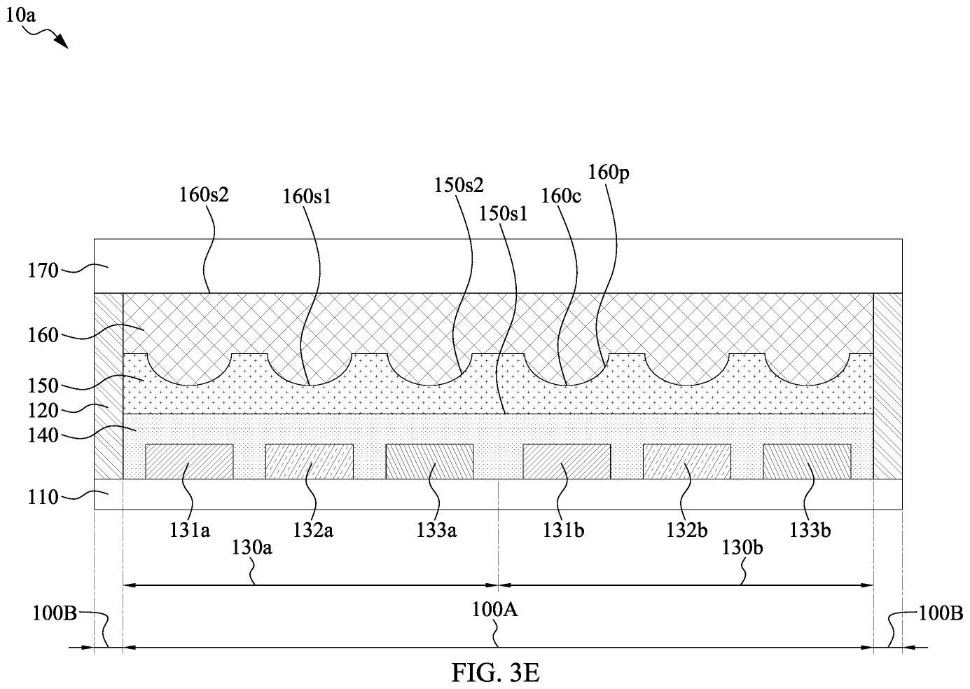

FIG. 3A to FIG. 3E show brief diagrams of the display device 10a in different manufacturing stages of a method according to some embodiments of the present disclosure.

Referring to FIG. 3A, the substrate 110 is provided. The support structure 120 is formed in the peripheral region 100B. The light emitting units 131a, 131b, 131c, 132a, 132b, and 133b are formed on the substrate 110. The filler layer 140 is formed on the substrate 110 to cover the light emitting units 131a, 131b, 131c, 132a, 132b, and 133b.

Referring to FIG. 3B, the photosensitive layer 150 is formed on the filler layer 140. The photosensitive layer 150 can be formed by coating, deposition or other appropriate manufacturing processes. The photosensitive layer 150 includes the surface 150s1 and the surface 150s2. In this stage, the surface 150s2 is a substantially flat surface.

Referring to FIG. 3C, operation 202 is performed to pattern or shaping the surface 150s2 of the photosensitive layer 150 such that the surface 150s2 of the photosensitive layer 150 has a curved surface. In some embodiments, operation 202 includes an exposure process, a development process, and other appropriate manufacturing processes. In some embodiments, the performing of operation 202 includes the use of a gray tone mask 210. The gray tone mask 210 can have different levels of light transmittance in different regions, so as to allow different amounts of light to pass through. In this embodiment, the surface 150s2 of the photosensitive layer 150 can be made to have a curved surface by using the gray tone mask 210.

In some embodiments, the gray tone mask 210 includes a plurality of slits (not shown), which can have different apertures. In some embodiments, a curvature of the surface 150s2 of the photosensitive layer 150 can be adjusted by the different apertures.

Referring to FIG. 3D, operation 204 is performed to form the optical element layer 160. Operation 204 can include forming the optical element layer 160 and curing the optical element layer 160. In some embodiments, the optical element layer 160 can be formed by deposition, coating or other appropriate manufacturing processes. In some embodiments, the curing of the optical element layer 160 can include heating or irradiation. In some embodiments, a temperature of the heating can be less than 100° C. At this temperature, no damage is caused on the light emitting units 131a, 131b, 131c, 132a, 132b, and 133b and other components. The optical element layer 160 includes the surface 160s1 and the surface 160s2. In this embodiment, the surface 160s1 of the optical element layer 160 is formed to correspond to the surface 150s2 of the photosensitive layer 150, and is not formed or shaped by a reflow operation.

In some embodiments, a curvature of the central portion 160c and a curvature of the peripheral portion 160p can be adjusted by the different apertures of the gray tone mask 210 (as shown in FIG. 3C). In some embodiments, the curvature of the central portion 160c and the curvature of the peripheral portion 160p are determined according to the emission angles (or beam angles) of the light emitting units 131a, 131b, 131c, 132a, 132b, and 133b. For example, the gray tone mask 210 can have a first slit and a second slit, wherein the first slit has a first aperture and the second slit has a second aperture different from the first aperture. In some embodiments, the curvature of the central portion 160c and the curvature of the peripheral portion 160p corresponding to the light emitting units 131a, 131b, 131c, 132a, 132b, and 133b are adjusted by the first slit and the second slit. For example, in some embodiments, the light emitting units 131a and 132a have different emission angles, so the surface 160s1 of the optical element layer 160 directly above the light emitting unit 131a and the surface 160s1 of the optical element layer 160 directly above the light emitting unit 132a have different curvatures. In some embodiments, the corresponding curvature of the central portion 160c and the corresponding curvature of the peripheral portion 160p are determined according to the curvatures above. In some embodiments, the curvature of the surface 150s2 of the photosensitive layer 150 is determined according to the curvature of the central portion 160c and the curvature of the peripheral portion 160p corresponding to the light emitting units 131a, 131b, 131c, 132a, 132b, and 133b. The curvature of the central portion 160c and the curvature of the peripheral portion 160p of the surface 160s1 of the optical element layer 160 can be adjusted based on the emission angles, which is predetermined or can be adjusted based on requirements, of the light emitting units 131a, 131b, 131c, 132a, 132b, and 133b.

Referring to FIG. 3E, the cover plate 170 is formed on the optical element layer 160 to manufacture the display device 10a.

In this embodiment, since the curved surface of the optical element layer 160 can be formed without performing the reflow operation, the photosensitive layer 150 and the optical element layer 160 can be formed on the filler layer 140. The photosensitive layer 150 and the optical element layer 160 do not need to be disposed on another carrier, and it is not necessary to perform an alignment operation before the carrier is adhered to the substrate 110. In this embodiment, yield rate loss caused by the alignment operation can be reduced. Moreover, in this embodiment, by forming the photosensitive layer 150 and the optical element layer 160 having curved contours with the use of the gray tone mask 210, the curved contour of the optical element layer 160 can be more accurately controlled, and the performance of the display device 10a can also be enhanced. Moreover, in this embodiment, the forming of the optical element layer 160 (or photosensitive layer 150) having a curved contour does not involve first patterning (including exposure, etching or other operations), so the use of a mask can be reduced. In this embodiment, by forming the photosensitive layer 150 by an organic material, different amounts of light are allowed to pass through with the use of the gray tone mask 210 to adjust the curvature of the surface of the optical element layer 160. Compared to the comparison example, the curvature of the surface of the optical element layer 160 according to the embodiments of the present disclosure can be more accurately controlled, hence enhancing the performance of the display device 10a.

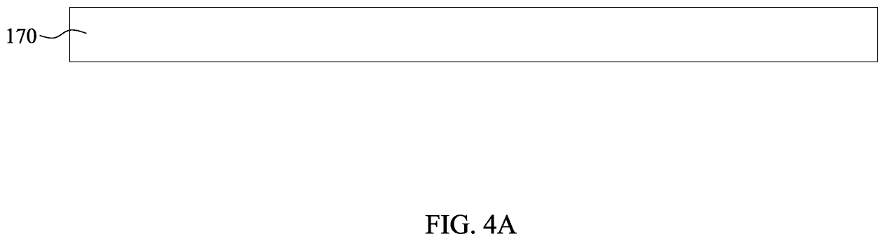

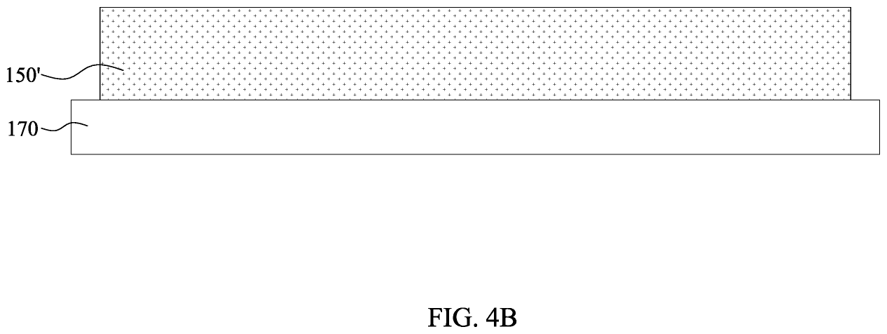

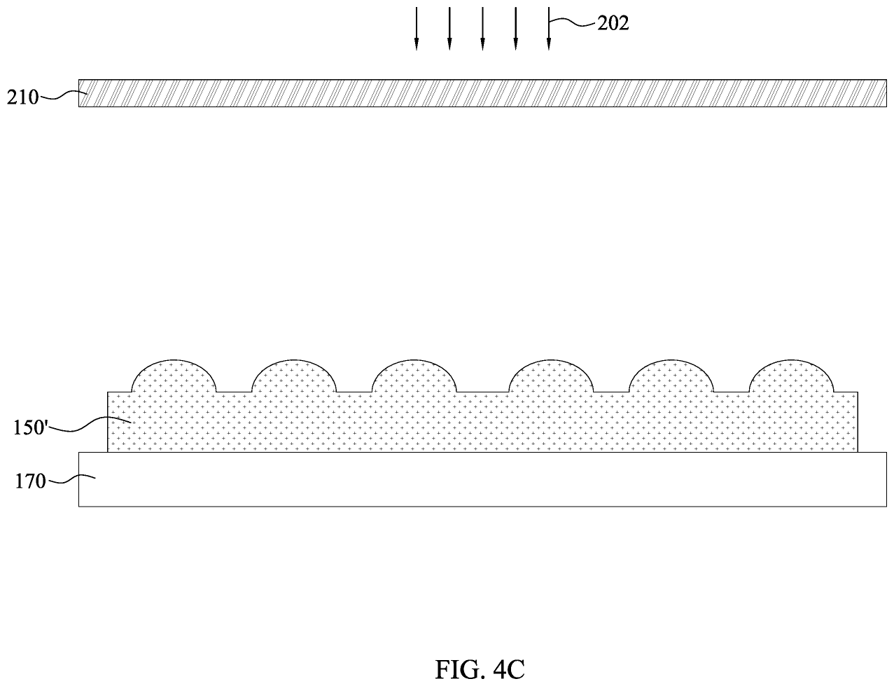

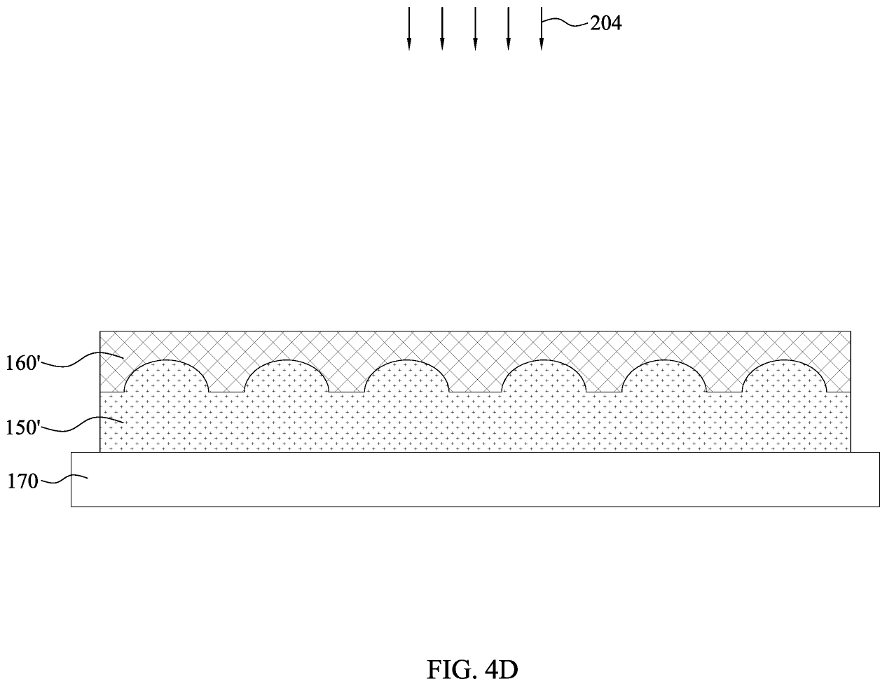

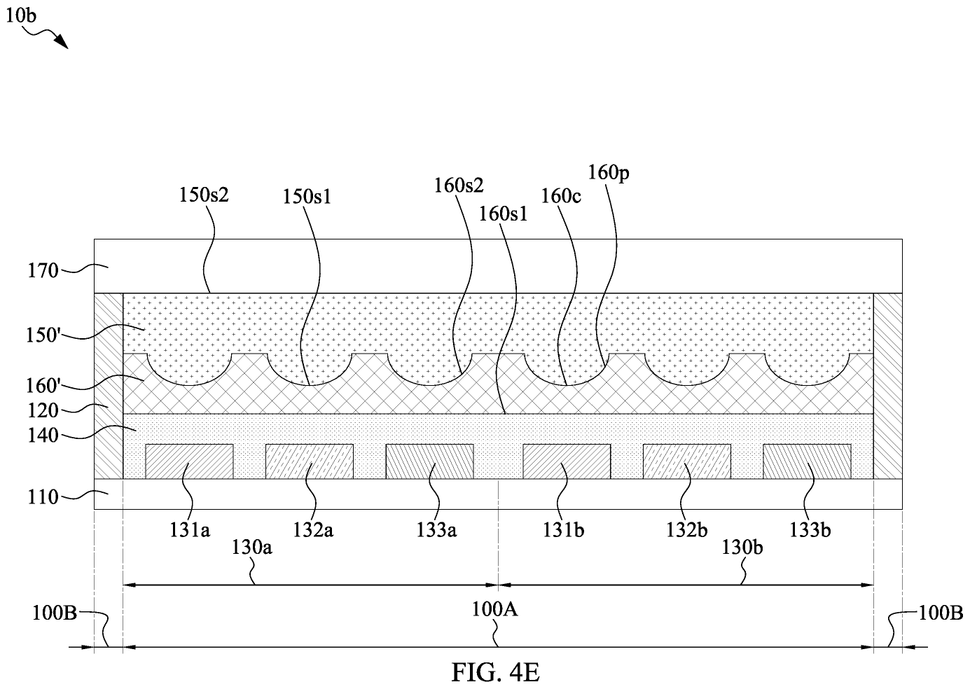

FIG. 4A to FIG. 4E show brief diagrams of the display device 10b in different manufacturing stages of a method according to some embodiments of the present disclosure.

Referring to FIG. 4A, the cover plate 170 is provided.

Referring to FIG. 4B, the photosensitive layer 150′ is formed on the cover plate 170. The photosensitive layer 150′ can be formed by coating, deposition or other appropriate manufacturing processes.

Referring to FIG. 4C, operation 202 is performed to pattern the photosensitive layer 150′, such that the photosensitive layer 150′ has a curved surface. In some embodiments, operation 202 includes an exposure process and other appropriate manufacturing processes. In some embodiments, the performing of operation 202 includes the use of a gray tone mask 210. The gray tone mask 210 can have different levels of light transmittance in different regions, so as to allow different amounts of light to pass through.

Referring to FIG. 4D, operation 204 is performed to form the optical element layer 160′. Operation 204 can include forming the optical element layer 160′ and curing the optical element layer 160′. In some embodiments, the optical element layer 160′ can be formed by deposition, coating or other appropriate manufacturing processes. In some embodiments, the curing of the optical element layer 160′ can include heating or irradiation. In some embodiments, a temperature of the heating can be less than 100° C. In this embodiment, the curved contour of the optical element layer 160′ is formed to correspond to the curved contour of the photosensitive layer 150′, and is not formed by a reflow operation.

Referring to FIG. 4E, the structure including the photosensitive layer 150′, the optical element layer 160′ and the cover plate 170 is bonded onto the substrate 110 to manufacture the display device 10b.

In this embodiment, by forming the photosensitive layer 150′ and the optical element layer 160′ having curved contours with the use of the gray tone mask 210, the curved contour of the optical element layer 160′ can be more accurately formed, and the performance of the display device 10b can also be enhanced. Moreover, in this embodiment, the forming of the photosensitive layer 150′ having a curved contour does not involve first patterning (including exposure, etching or other operations) the photosensitive layer 150′, so the use of a mask can be reduced.

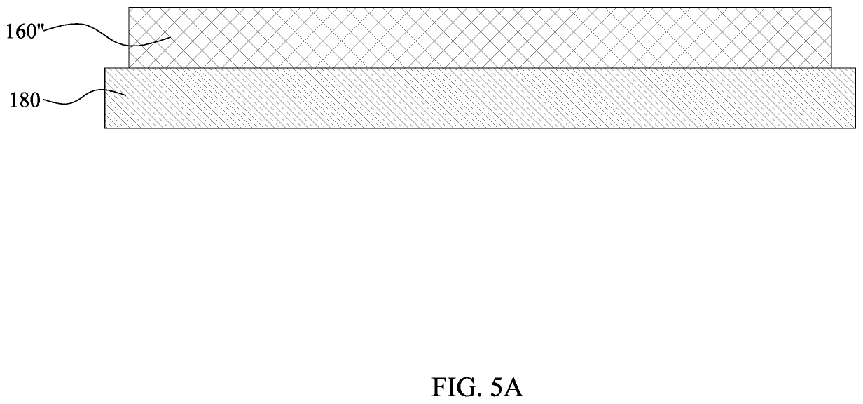

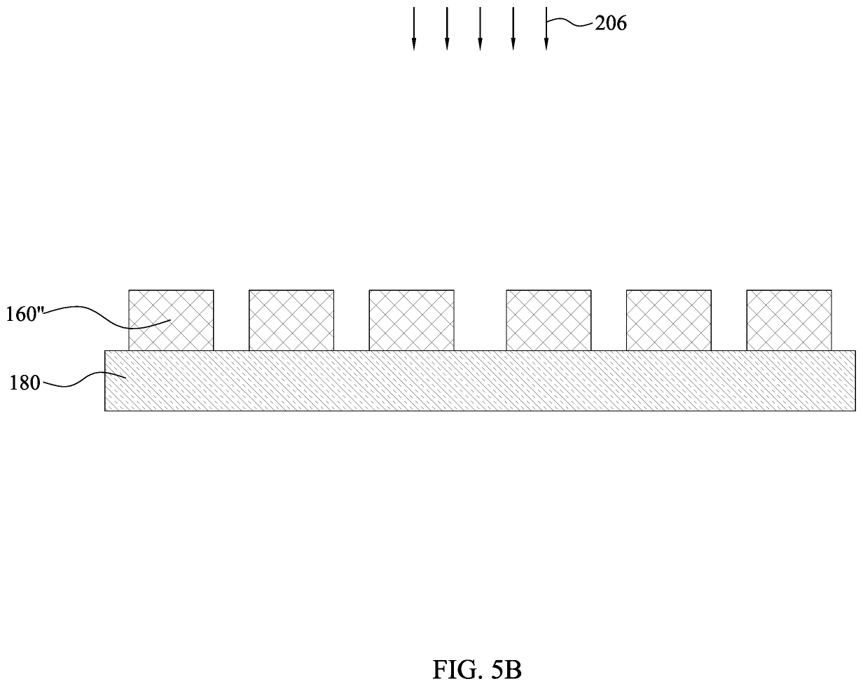

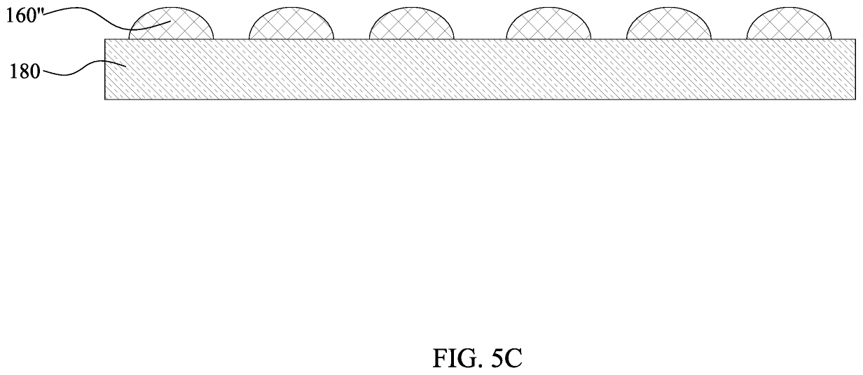

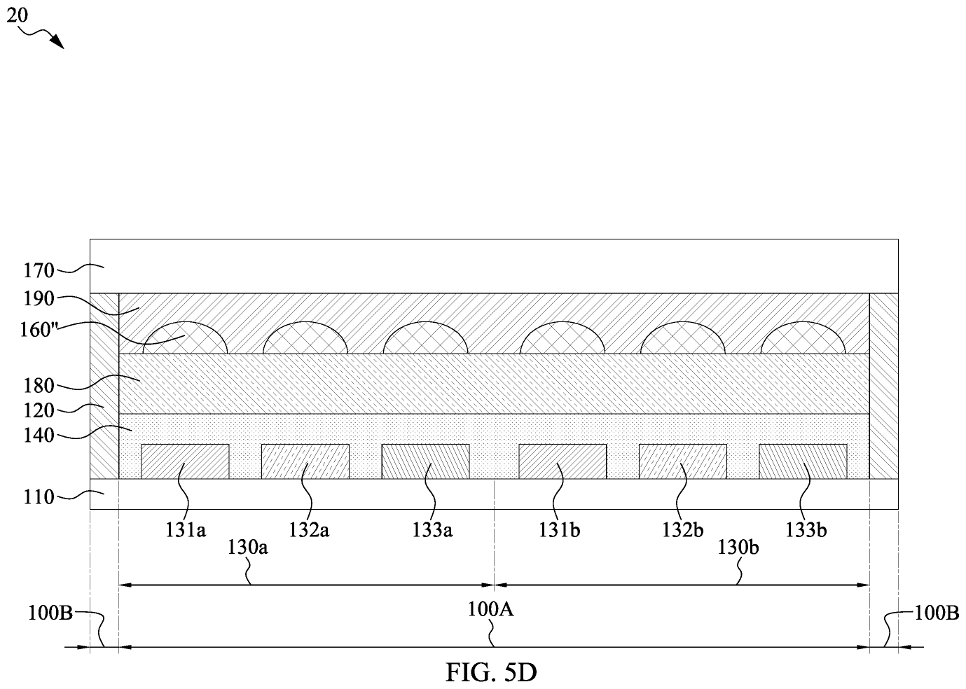

FIG. 5A to FIG. 5D are brief diagrams of a display device 20 in different manufacturing stages of a method of the comparison example.

Referring to FIG. 5A, a carrier board 180 is provided, and an optical element layer 160″ is formed on the carrier board 180.

Referring to FIG. 5B, operation 206 is performed so that the optical element layer 160″ has a plurality of portions separated from one another. Operation 206 includes patterning the optical element layer 160″. The patterning of the optical element layer 160″ can include exposure, etching or other operations.

Referring to FIG. 5C, operation 208 is performed so that the optical element layer 160″ has a curved surface. Operation 208 includes a reflow operation at a temperature greater than 130° C.

Referring to FIG. 5D, the optical element layer 160″ having a curved surface and the carrier board 180 are bonded onto a substrate 110 and a filler layer 190 is formed, so as to form the display device 20. In the comparison example, since the carrier board 180 needs to be bonded onto the substrate 110, an alignment operation is needed, resulting in a yield rate poorer than that of the method shown in FIG. 3A to FIG. 3E. In addition, the optical element layer 160″ of the comparison example is formed by a reflow operation, and the precision of the curved surface is not as outstanding as that that of the methods shown in FIG. 3A to FIG. 3E and FIG. 4A to FIG. 4E.

The present disclosure accordingly provides a display device. The display device includes a substrate, a light emitting unit, an optical element layer and a photosensitive layer. The light emitting unit is disposed on the substrate. The optical element layer is disposed on the light emitting unit. The optical element layer has a first curved surface. The first curved surface has a central portion and a peripheral portion. The central portion is closer to the substrate than the peripheral portion. The photosensitive layer is in contact with the optical element layer.

In some embodiments, the optical element layer includes a lens.

In some embodiments, the display device excludes a filter layer.

In some embodiments, the light emitting unit is an organic light emitting diode (OLED).

In some embodiments, the display device further includes a cover plate. The cover plate is disposed on the optical element layer. The optical element layer is in direct contact with the cover plate.

In some embodiments, the photosensitive layer has a second curved surface, wherein the second curved surface of the photosensitive layer is in contact with the first curved surface of the optical element layer.

The present disclosure accordingly provides a method for manufacturing a display device. The method includes: providing a substrate; forming a light emitting unit on the substrate; providing an optical element layer on the light emitting unit, wherein the optical element layer has a first curved surface, the first curved surface has a central portion and a peripheral portion, and the central portion is closer to the substrate than the peripheral portion; and providing a cover plate to cover the optical element layer.

In some embodiments, the forming of the photosensitive layer includes: patterning the photosensitive layer by using a gray tone mask, so that the photosensitive layer has a second curved surface.

In some embodiments, the forming of the photosensitive layer includes:

forming an optical element layer on the second curved surface of the photosensitive layer, and forming a first curved surface of the optical element layer; and curing the optical element layer.

In some embodiments, the curing of the optical element layer includes: performing a heating operation to cure the optical element layer, wherein a temperature of the heating operation is less than 100° C.

In some embodiments, the method further includes: forming a photosensitive layer having a second curve surface, wherein the optical element layer is formed on the second curved surface of the photosensitive layer.

In some embodiments, the forming of the optical element layer includes: forming the photosensitive layer on the light emitting unit; performing an exposure operation to form the second curved surface of the photosensitive layer; and forming the optical element layer on the second curved surface of the photosensitive layer.

In some embodiments, the forming of the optical element layer includes: forming the photosensitive layer on a cover plate; performing an exposure operation to form the second curved surface of the photosensitive layer; forming the optical element layer on the second curved surface of the photosensitive layer; and adhering the optical element layer onto the light emitting unit.

In some embodiments, the forming of the optical element layer excludes performing a reflow operation.

In some embodiments, a temperature of the forming of the photosensitive layer is less than 100° C.

In some embodiments, the forming of the optical element layer excludes patterning the optical element layer.

In some embodiments, the forming of the optical element layer excludes exposing the optical element layer.

In some embodiments, the forming of the optical element layer excludes etching the optical element layer.

In some embodiments, the gray tone mask has a first slit and a second slit, wherein the first slit has a first aperture and the second slit has a second aperture different from the first aperture. The method for manufacturing a display device further include determining a first curvature of a central portion and a second curvature of a peripheral portion of the first curved surface according to an emission angle of the light emitting unit, and adjusting the first curvature and the second curvature by the first slit and the second slit.

In some embodiments, a diameter of the peripheral portion is between 1.01 and 1.5 times a width of the light emitting unit.

The features of some embodiments are given in brief in the description above for a person skilled in the art to better understand various aspects of the present disclosure. A person skilled in the art would be able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the disclosure of the present application, and various changes, substitutions and replacements may be made by a person skilled in the art without departing from the spirit and scope of the present disclosure.

In addition, the scope of the present application is not limited to the specific embodiments of the processes, machinery, manufacturing, substance compositions, means, methods or steps given in the detailed description. A person of ordinary skill in the art would be able to understand from the disclosed details of the present disclosure that existing or future processes, machinery, manufacturing, substance compositions, means, methods or steps that have the same functions or achieve substantially the same results as the corresponding embodiments given in the literature can be used according to the present disclosure. Accordingly, these processes, machinery, manufacturing, substance compositions, means, methods and steps to be encompassed within the scope of the appended claims of the present application.

What is claimed is:

1. A display device, comprising:
a substrate;
a light emitting unit, disposed on the substrate;
an optical element layer, disposed on the light emitting unit, the optical element layer having a first curved surface, wherein the first curved surface has a central portion and a peripheral portion, and the central portion is closer to the substrate than the peripheral portion; and
a photosensitive layer, being in contact with the optical element layer.

2. The display device according to claim 1, wherein the optical element layer comprises a lens.

3. The display device of claim 1, wherein the display device is free of a filter layer.

4. The display device of claim 1, wherein the light emitting unit is an organic light emitting diode (OLED).

5. The display device according to claim 1, further comprising:
a cover plate, disposed on the optical element layer, wherein the optical element layer is in direct contact with the cover plate.

6. The display device according to claim 1, wherein the photosensitive layer has a second curved surface, and the second curved surface of the photosensitive layer is in contact with the first curved surface of the optical element layer.

7. A method for manufacturing a display device, comprising:
providing a substrate;
forming a light emitting unit on the substrate;
providing an optical element layer on the light emitting unit, the optical element layer having a first curved surface, wherein the first curved surface has a central portion and a peripheral portion, and the central portion is closer to the substrate than the peripheral portion; and
providing a cover plate to cover the optical element layer.

8. The method according to claim 7, further comprising:
forming a photosensitive layer having a second curve surface, wherein the optical element layer is formed on the second curved surface of the photosensitive layer.

9. The method according to claim 8, wherein the forming of the photosensitive layer comprises:
patterning the photosensitive layer by using a gray tone mask to form the second curved surface of the photosensitive layer.

10. The method according to claim 9, wherein the forming of the photosensitive layer comprises:
forming the optical element layer with the first curved surface on the second curved surface of the photosensitive layer; and
curing the optical element layer.

11. The method according to claim 10, wherein the curing of the optical element layer comprises:
performing a heating operation to cure the optical element layer, wherein a temperature of the heating operation is less than 100° C.

12. The method according to claim 8, wherein the forming of the optical element layer comprises:
forming the photosensitive layer on the light emitting unit;
performing an exposure operation to form the second curved surface of the photosensitive layer; and
forming the optical element layer on the second curved surface of the photosensitive layer.

13. The method according to claim 8, wherein the forming of the optical element layer comprises:
forming the photosensitive layer on the cover plate;
performing an exposure operation to form the second curved surface of the photosensitive layer;
forming the optical element layer on the second curved surface of the photosensitive layer; and
attaching the optical element layer to the light emitting unit.

14. The method according to claim 7, wherein the forming of the optical element layer is free of performing a reflow operation.

15. The method according to claim 14, wherein a temperature of the forming of the optical element layer is less than 100° C.

16. The method according to claim 7, wherein the forming of the optical element layer is free of patterning the optical element layer.

17. The method according to claim 16, wherein the forming of the optical element layer is free of exposing the optical element layer.

18. The method according to claim 16, wherein the forming of the optical element layer is free of etching the optical element layer.

19. The method according to claim 9, wherein the gray tone mask has a first slit and a second slit, the first slit has a first aperture and the second slit has a second aperture different from the first aperture, wherein the method comprises:
determining a first curvature of the central portion and a second curvature of the peripheral portion of the first curved surface according to an emission angle of the light emitting unit; and
adjusting the first curvature and the second curvature of the first curved surface by the first slit and the second slit.

20. The method according to claim 7, wherein a diameter of the peripheral portion is between 1.01 and 1.5 times a width of the light emitting unit.
